(19) United States
(12) Patent Application Publication
(10) Pub. No.: US 2026/0037426 A1
(43) Pub. Date: Feb. 5, 2026

(54) MEMORY DEVICE, OPERATING METHOD AND MEMORY SYSTEM

(71) Applicant: YANGTZE MEMORY TECHNOLOGIES CO., LTD., Wuhan (CN)

(72) Inventors: Dong HE, Wuhan (CN); Bo LI, Wuhan (CN); Jing WEI

(21) Appl. No.: 19/011,399

(22) Filed: Jan. 6, 2025

(30) Foreign Application Priority Data
Aug. 1, 2024 (CN) 2024110555984

(51) Int. Cl. G06F 12/02

(52) U.S. Cl. CPC G06F 12/0246

(57) ABSTRACT

Implementations of the present application provide a memory device, an operating method and a memory system. Here, the memory device includes: a memory cell array including at least one memory block; peripheral circuits coupled to the memory blocks and including a storage structure, wherein the peripheral circuit are configure to: receive and parse an operation command to obtain at least one address information; read, from the storage structure, the state information of the corresponding memory block to be operated according to each address information with the state information indicates whether the memory block is a bad block; and generate a stop signal in response to the state information of a memory block to be operated indicating that the memory block to be operated is a bad block, wherein the stop signal indicates to cease performing the operations on the memory block to be operated.

### CROSS-REFERENCE TO RELATED APPLICATIONS

The present application claims priority to Chinese Patent Application No. 2024110555984, which was filed Aug. 1, 2024, and is hereby incorporated herein by reference in its entirety.

### TECHNICAL FIELD

The present application relates to the field of semiconductor storage technologies, and in particular to a memory device, an operating method and a memory system.

### BACKGROUND

A memory device is a storage apparatus used for saving information in modern information technologies. As a typical nonvolatile semiconductor memory, an NAND (Not-And) memory is becoming a main stream product in the market of storage due to its relatively high storage density, controllable production costs, appropriate program and erase speeds and retention characteristics.

### SUMMARY

In a first aspect, according to the present implementation, a memory device is provided, the memory device including: a memory cell array, which includes a memory plane including at least one memory block; peripheral circuits coupled to the memory block(s) included in the memory cell array and including a storage structure, wherein the peripheral circuits are configured to: receive and parse an operation command to obtain at least one piece of address information; read, from the storage structure, the state information of the memory block to be operated in a corresponding memory plane according to each piece of address information with the state information indicates whether the memory block is a bad block; and generate a stop signal in response to the state information of a memory block to be operated indicating that the memory block to be operated is a bad block, with the stop signal indicates to cease performing operations on the memory block to be operated.

In the above-described scheme, the peripheral circuits are further configured to: in response to the at least one piece of address information including a first piece of address information, read, from the storage structure, the state information of a first memory block to be operated included in a first memory plane according to the first piece of address information; and
in response to the state information of the first memory block to be operated indicating that the first memory block to be operated is a bad block, generate a first stop signal that indicates to cease performing a first operation on the first memory block to be operated.

In the above-described scheme, the peripheral circuits are further configured to: in response to the state information of the first memory block to be operated indicating that the first memory block to be operated is not a bad block, generate a first operation signal that indicates to perform the first operation on the first memory block to be operated, wherein the first operation includes one of an erase operation, a program operation, or a read operation.

In the above-described scheme, the peripheral circuits are further configured to: in response to success of execution of the first operation, output a first indication signal that indicates the success of execution of the first operation.

In the above-described scheme, the peripheral circuits are further configured to: in response to the at least one piece of address information further including a second piece of address information, read, from the storage structure, the state information of a second memory block to be operated included in a second memory plane according to the second piece of address information, wherein the number of the second piece of address information is one or two; and in response to the state information of the second memory block to be operated indicating that the second memory block to be operated is a bad block, generate a second stop signal that indicates to cease performing a second operation on the second memory block to be operated.

In the above-described scheme, the peripheral circuits are further configured to: in response to the state information of the second memory block to be operated indicating that the second memory block to be operated is not a bad block, generate the second operation signal that indicates to perform the second operation on the second memory block to be operated, and in response to success of execution of both the first operation and the second operation, output a second indication signal that indicates the success of execution of both the first operation and the second operation.

In the above-described scheme, the storage structure includes an SRAM having a block state information table buffered therein. The state information of individual memory blocks included in a memory cell array is recorded in the block state information table, and each piece of state information includes a first flag or a second flag. The first flag is used to indicate a corresponding memory block is a bad block and the second flag is used to indicate a corresponding memory block is a normal block.

In the above-described scheme, each piece of state information indicates a leave-factory state of a corresponding memory block in the memory cell array. The leave-factory state includes whether a memory block is a bad block or a normal block.

In the above-described scheme, the block state information table is stored at a dedicated location in the memory cell array; the peripheral circuits are further configured to: when the memory device is powered on, perform a loading operation to buffer the block state information table into the SRAM.

In the above-described scheme, each first flag occupies one bit in the SRAM and each second flag occupies one bit in the SRAM.

In a second aspect, a method of operating a memory device is provided in an implementation of the present application, which includes: receiving and parsing an operation command to obtain at least one piece of address information; reading, from the storage structure included in the peripheral circuits of the memory device, the state information of a memory block to be operated in the corresponding memory plane of the memory device according to each piece of address information; generating a stop signal in response to the state information of a memory block to be operated indicating that the memory block to be operated is a bad block, with the stop signal used to indicate to cease performing the operations on the memory block to be operated.

In the above-described scheme, the method further includes: in response to the at least one piece of address information including a first piece of address information, reading, from the storage structure, the state information of a first memory block to be operated included in a first memory plane according to the first piece of address information; and in response to the state information of the first memory block to be operated indicating that the first memory block to be operated is a bad block, generating a first stop signal that indicates to cease performing a first operation on the first memory block to be operated.

In the above-described scheme, the method further includes: in response to the state information of the first memory block to be operated indicating that the first memory block to be operated is not a bad block, generating a first operation signal that indicates to perform the first operation on the first memory block to be operated, wherein the first operation may include one of an erase operation, a program operation, or a read operation.

In the above-described scheme, the method further includes: in response to success of execution of the first operation, outputting a first indication signal that indicates the success of execution of the first operation.

In the above-described scheme, the method further includes: in response to the at least one piece of address information further including a second piece of address information, reading, from the storage structure, the state information of a second memory block to be operated included in a second memory plane of the memory device according to the second piece of address information, wherein the number of the second piece of address information is one or two; and in response to the state information of the second memory block to be operated indicating that the second memory block to be operated is a bad block, generating a second stop signal that indicates to cease performing a second operation on the second memory block to be operated.

In the above-described scheme, the method further includes: in response to the state information of the second memory block to be operated indicating that the second memory block to be operated is not a bad block, generating a second operation signal that indicates to perform the second operation on the second memory block to be operated, and in response to success of execution of both the first operation and the second operation, generating a second indication signal that indicates the success of execution of both the first operation and the second operation.

In the above-described scheme, the storage structure includes an SRAM having a block state information table buffered therein. The state information of individual memory blocks included in a memory cell array is recorded in the block state information table, and each piece of state information includes a first flag and a second flag. The first flag is used to indicate a corresponding memory block is a bad block and the second flag is used to indicate a corresponding memory block is a normal block.

In the above-described scheme, the state information indicates a leave-factory state of a corresponding memory block in the memory cell array. The leave-factory state includes whether a memory block is a bad block or a normal block.

In the above-described scheme, the block state information table is stored at a dedicated location in the memory cell array of the memory device; the method further includes: when the memory device is powered on, performing a loading operation to buffer the block state information table into the SRAM.

In a third aspect, implementations of the present application further provide a memory system including: one or more memory devices described in any of the foregoing paragraphs; and a memory controller that is coupled to the memory device(s) and configured to control the memory device(s).

Implementations of the present application provide a memory device, an operating method and a memory system. Here, the memory device includes: a memory cell array, which includes a memory plane including at least one memory block; peripheral circuits coupled to the memory block(s) included in the memory cell array and including a storage structure, wherein the peripheral circuits are configured to: receive and parse an operation command to obtain at least one piece of address information; read, from the storage structure, the state information of the memory block to be operated in a corresponding memory plane according to each piece of address information with the state information indicates whether the memory block is a bad block; and generate a stop signal in response to the state information of a memory block to be operated indicating that the memory block to be operated is a bad block, with the stop signal indicates to cease performing the operations on the memory block to be operated. In the memory devices provided by implementations of the present application, a storage structure is disposed in peripheral circuits to store information indicating whether each memory block is a bad block, so that when an operation needs to be performed on a memory block, it can be determined whether the operation should be performed on the memory block only by reading the information from the storage structure and parsing the information. The scheme, in which whether an operation should be performed on a memory block is indicated only by reading the information indicating whether the memory block is a bad block from the arranged storage structure, is simple to operate and easy to realize, and can save the area along the word line direction of the memory device, so that more area can be distributed to the driving circuits for the memory cells coupled to word lines requiring a high program voltage and thereby relatively high program voltages can be provided to satisfy requirements.

### BRIEF DESCRIPTION OF THE DRAWINGS

In the figures drawn not necessarily to scale, the same reference numerals may describe similar parts in different views. The same numerals with different character suffixes may represent different instances of similar components. The accompanying drawings depict various implementations discussed in the present document in general for illustration rather than limitation.

FIG. 1 is a structural diagram of a memory device provided in an implementation of the present application;

FIG. 2 is a structural diagram of a memory cell array included in a memory device provided in an implementation of the present application;

FIG. 3 is a structural diagram of a memory cell array provided in an implementation of the present application;

FIG. 4 is a cross sectional diagram of an example memory array including NAND memory strings provided in an implementation of the present application;

FIG. 5 is a structural diagram illustrating a logical configuration of a memory cell array included in a NAND flash chip provided in an implementation of the present application;

FIG. 6 is a diagram of contents included in the address information provided in an implementation of the present application;

FIG. 7 is an example structural diagram of a super memory block provided in an implementation of the present application;

FIG. 8 is a structural diagram of a block state information table in an SRAM provided in an implementation of the present application;

FIG. 9 is a flow chart of some operations when a first operation is to performed on individual memory blocks in a memory device using the state information of the individual memory blocks stored in an SRAM provided in an implementation of the present application;

FIG. 10 is a flow chart of performing a first operation on memory blocks included in a single Plane of a memory device provided in an implementation of the present application;

FIG. 11 is a flow chart of performing a first operation simultaneously on memory blocks included in multiple Planes of a memory device provided in an implementation of the present application;

FIG. 12 is a flow chart of a method of operating a memory device provided in an implementation of the present application;

FIG. 13 is a structural diagram of a memory system provided in an implementation of the present application;

FIG. 14 is a structural diagram of a memory card including a memory system provided in an implementation of the present application;

FIG. 15 is a structural diagram of a solid state drive including a memory system provided in an implementation of the present application;

FIG. 16 is an example system diagram including a memory system provided in an implementation of the present application; and

FIG. 17 is a structural diagram of a memory controller provided in an implementation of the present application.

### DETAILED DESCRIPTION

Hereinafter, example implementations disclosed by the present application will be described in more detail with reference to accompanying drawings. Although example implementations of the present application are illustrated in accompanying drawings, it should be understood that the present application can be embodied in various forms and is not limited to specific example described herein. On the contrary, the example are provided for more thorough understanding of the present application and to convey the scope the present application fully to those skilled in the art.

In the description hereafter, many specific details are provided to facilitate more thorough understanding of the present application. However, it is apparent for those skilled in the art that the present application can be implemented without one or more of these details. In other examples, in order not to obscure the present application, some technical features well known in the art will not be described. For example to say, not all features of practical implementations will be described herein and well-known functions and structures will not be described in detail.

In accompanying drawings, dimensions and relative sizes of layers, regions and elements may be exaggerated for clearance. The same reference numerals refer to the same elements throughout the specification.

It should be appreciated that when an element or a layer is said to be “over”, “adjacent to”, “connected to” or “coupled to” another element or layer, it may be directly over, adjacent to, connected to or coupled to the another element or layer or an intervening element or layer may exist therebetween. On the contrary, when an element is said to be “directly on”, “directly adjacent to”, “directly connected to” or “directly coupled to” another element or layer, there is no intervening element or layer therebetween. It should be appreciated that although various elements, components, regions, at least one of layers or parts may be described using terms “first”, “second”, “third” or the like, they are not limited by those terms. The terms are only used to distinguish one element, component, region, layer or part from another element, component, region, layer or part. Therefore, a first element, component, region, layer or part discussed hereafter may be instead expressed as a second element, component, region, layer or part without departing from the teaching of the present application. When a second element, component, region, layer or part is in discussion, it is not intended to indicate that a first element, component, region, layer or part must exist in the present application.

Spatially relative terms, such as “below”, “beneath”, “lower”, “under”, “over” and “above”, are used herein for case of description to explain the relationship of one element or feature with respect to other elements or features as shown in the figures. It should be appreciated that, in addition to the orientations shown in the figures, different orientations of devices in use and operation are further intended to be covered by those spatially relative terms. For example, if a device is turned upside down, the element or feature described to be “beneath”, “under” or “below” another element or feature will have the orientation of being “over” the another element or feature. Therefore, example terms “beneath” and “under” may include orientations of both “below” and “above”. Devices may be otherwise oriented (rotated 90 degrees or at other orientations) and the spatially relative descriptors used herein may likewise be interpreted accordingly.

Terminology is used herein only for description of specific implementations and in no way for limiting the present application. As used herein, the terms “a”, “an” and “the” in singular forms are further intended to cover plural forms, unless the context clearly indicates otherwise. It is further be appreciated that at least one of terms “comprise” or “including”, as used in the specification, specify presence of at least one of the mentioned features, integers, steps, operations, elements or components, but do not exclude presence or addition of at least one of one or more other features, integers, steps, operations, elements, components or combinations thereof. As used herein, the term “and/or” includes any and all combinations of relevant listed items.

In order to disclose characteristics and technical contents of implementations of the present application more thoroughly, example of implementations of the present application will be described in detail hereafter with reference to accompanying drawings, which are only for reference and illustration and not for definition of implementations of the present application.

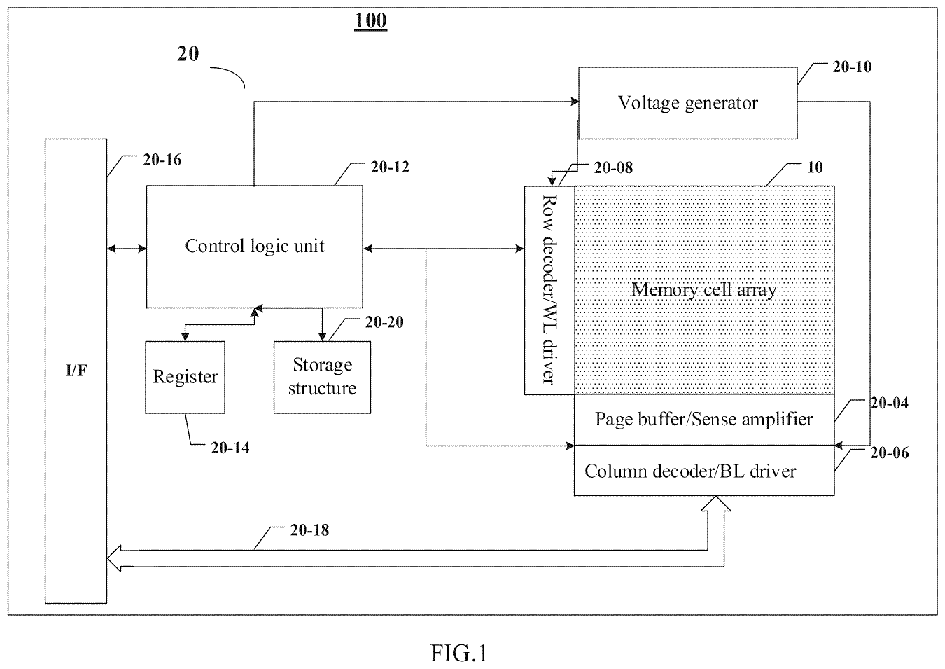

FIG. 1 illustrates a structural diagram of a memory device provided in an implementation of the present application. As shown in FIG. 1, the memory device 100 includes:
a memory cell array 10 that may include at least one memory block;
peripheral circuits 20 coupled to the memory block(s) included in the memory cell array and including a storage structure 20-20, wherein the peripheral circuits 20 may be configured to: receive and parse an operation command to obtain at least one piece of address information; read, from the storage structure, the state information of the memory block to be operated included in the corresponding memory plane according to each piece of address information with the state information indicates whether the memory block is a bad block; and generate a stop signal in response to the state information of a memory block to be operated indicating that the memory block to be operated is a bad block, with the stop signal indicates to cease performing the operations on the memory block to be operated.

The memory device 100 herein may be a device used to store at least one of programs or data including a storage medium used for storage of at least one of programs or data (e.g., a memory cell array) and various circuits (that can be collectively called “a peripheral circuit”) used to control the memory cells included in the memory cell array and further store at least one of the programs or data into the memory cell array.

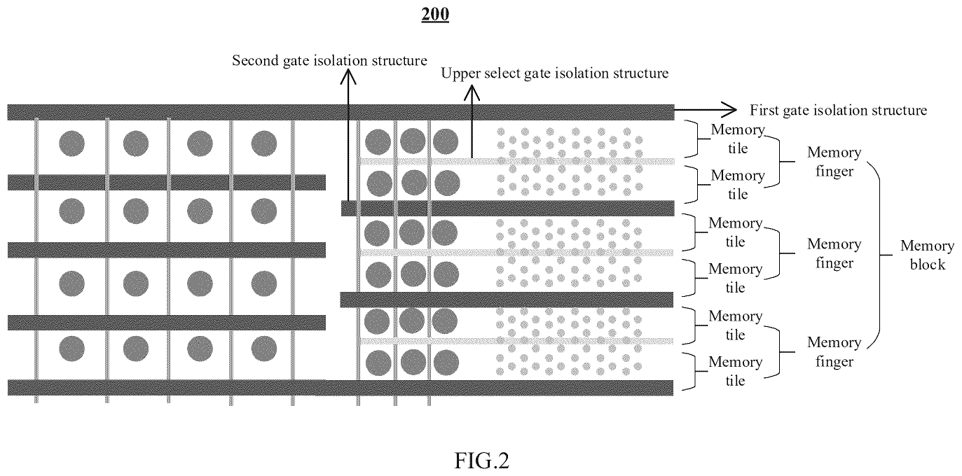

Referring to FIG. 2, which illustrates a structural diagram of a memory cell array 200 of a three-dimensional (3D) NAND memory device. As shown in FIG. 2, the memory cell array of the 3D NAND memory device is composed of a number of rows of memory cells that are parallel and staggered with respect to each other and parallel to gate isolation structures. Every two rows of memory cells are isolated from other rows by a gate isolation structure and an upper select gate isolation structure. Each row of memory cells includes a plurality of memory cells. The gate isolation structures may include first gate isolation structures and second isolation structures. The first gate isolation structures are used to divide the memory cell array into a plurality of memory blocks and a plurality of second gate isolation structures may divide the memory blocks into a plurality of memory fingers. Each memory finger may be divided into two sections by an upper select gate isolation structure disposed in the middle of the memory finger, resulting in two memory tiles. FIG. 2 shows that one memory block includes 6 memory tiles. However, in practical applications, the number of memory tiles in one memory block is not limited to this.

In some implementations, each memory block may couple a plurality of word lines and the plurality of memory cells coupled by each word line, which is controlled separately, constitute a memory page (a physical page here). Illustratively, in FIG. 2, all the memory cells coupled by one word line in each memory tile constitute a memory page.

It is to be noted that the number of the memory cell rows between a gate isolation structure and an upper select gate isolation structure given in FIG. 2 is only an example, and the number of the memory cell rows included in one memory finger of a 3D NAND memory is not limited to this in the present application. In practical applications, the number of the memory cell rows included in one memory finger can be adjusted according to practical conditions, for example, to be 2, 4, 8, 16 etc.

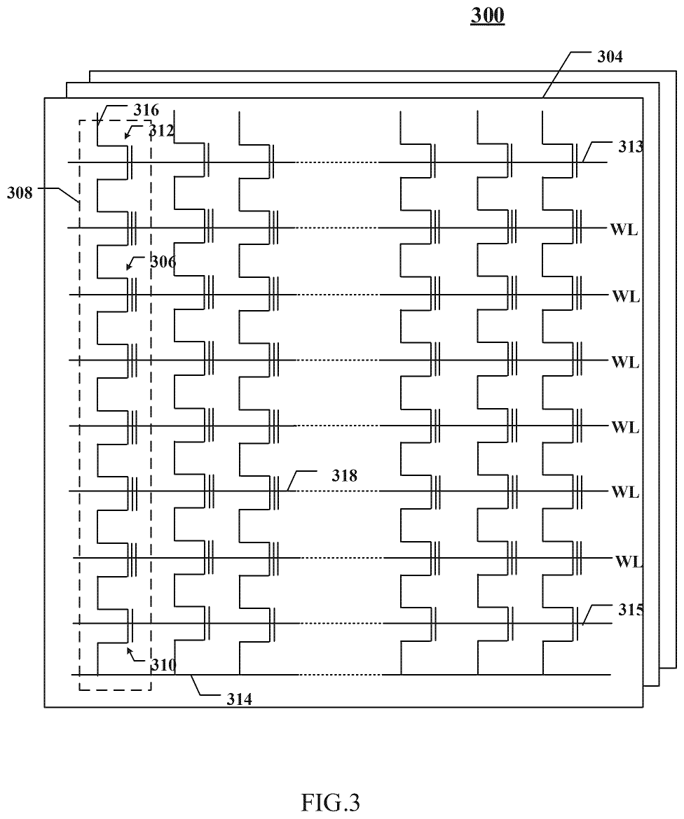

Referring to FIG. 3, which illustrates a structural diagram of a memory cell array. As shown in FIG. 3, the memory cell array 300 may be an NAND memory cell array, which is one example of the above-mentioned memory cell array 10. The memory cells 306 of the memory cell array 300 are provided in the form of an array of NAND memory strings 308 each extending vertically above a substrate (not shown). In some implementations, each NAND memory string 308 includes a plurality of memory cells 306 coupled in series and stacked vertically. Each memory cell 306 can retain a continuous analog value, for example, a voltage or charge, depending on the number of electrons trapped in the storage region of the memory cell 306. Each memory cell 306 may be a memory cell of a floating-gate type that includes a floating-gate transistor, or a memory cell of a charge trapping type that includes a charge trapping transistor.

In some implementations, each memory cell 306 is a single-level cell (SLC) that has two possible data states and can therefore store one bit of data. For example, the first data state “0” may correspond to a first voltage range, and the second data state “1” may correspond to a second voltage range. In some implementations, the first voltage range and the second voltage range may be referred to as the threshold voltage distribution of the memory cell. In some implementations, each memory cell 306 may be a multi level cell (MLC). For example, an MLC may store two bits each cell (further referred to as a double level cell (DLC)). For another example, each cell stores three bits (further referred to as a trinary level cell (TLC)). For yet another example, each cell stores four bits (further referred to as a quadruple level cell QLC)). Here, no matter what type a memory cell belongs to, its data states include an erased state and (one or more) programmed states and when a program operation is performed on a memory cell, the memory cell is programmed from the erased state to a programmed state. Generally, the voltage values in the voltage range corresponding to a programmed state of a memory cell is relatively high.

As shown in FIG. 3, each NAND memory string 308 may include a source select gate (SSG) 310 at its source end and a drain select gate (DSG) 312 at its drain end. The SSG 310 and the DSG 312 may be configured to activate a selected NAND memory string 308 (a column in the array) during a read operation and a program (or write) operation. In some implementations, the sources of the NAND memory strings 308 in the same memory block 304 are coupled to each other through the same source line (SL) 314 (e.g., a common SL). For example, in accordance with some example, all the NAND memory strings 308 in the same memory block 304 have an array common source (ACS). In according to some example, the DSG 312 of each NAND memory string 308 is coupled to a corresponding bit line 316 and data can be read from and written to the bit line 316 through an output bus (not shown). In some example, each NAND memory string 308 is configured to be selected or deselected by at least one of applying a select voltage (e.g., a voltage higher than the threshold voltage of the transistor having the DSG 312) or a deselect voltage (e.g., 0 volt (V)) to the corresponding DSG 312 through one or more drain select lines or top select lines 313 or applying a select voltage (e.g., a voltage higher than the threshold voltage of the transistor having the SSG 310) or a deselect voltage (e.g., OV) to the corresponding SSG 310 through one or more source select lines or bottom select lines 315.

As shown FIG. 3, the NAND memory strings 308 can be organized into a plurality of memory blocks 304, each of which may have a common source line 314 (e.g., coupled to the ground). In some implementations, each memory block 304 is a basic data unit used for an erase operation. For example, all the memory cells 306 in the same memory block 304 can be erased simultaneously. In order to erase the memory cells 306 in a selected memory block 304, an erase voltage (Vers), for example, a high positive voltage (20V or higher) is bias coupled to the source lines 314 of the selected memory block 304 and the unselected memory blocks 304 in the same plane as the selected memory block 304. It should be understood that, in some examples, an erase operation may be performed at a half-block level, a quarter-block level or a level having any suitable number of blocks or any suitable fraction of a block. As shown in FIG. 3, memory cells 306 of adjacent NAND memory strings 308 may be coupled to each other through word lines 318. For example, the same word line 318 may be coupled to the memory cells at the same position in a plurality of memory strings, e.g., to the corresponding memory cells.

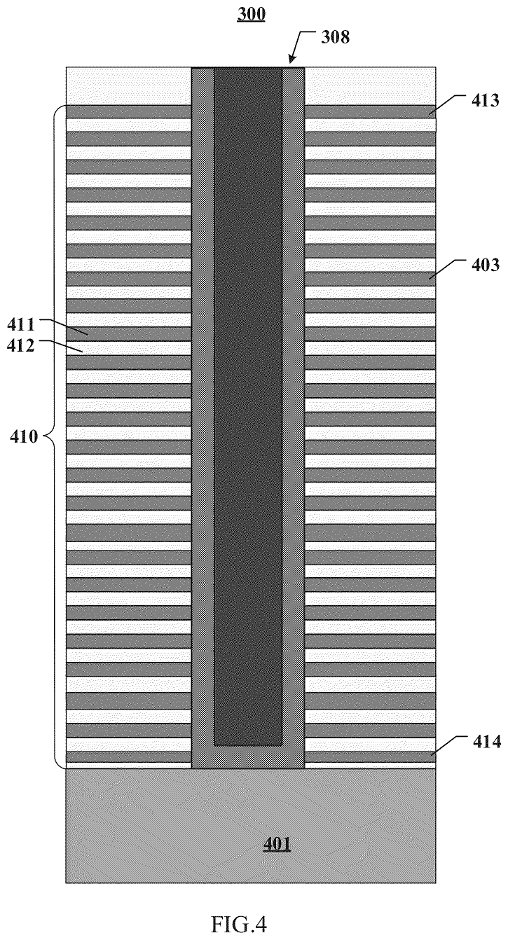

FIG. 4 illustrates a cross-sectional side view of an example memory cell array 300 including NAND memory strings 308 in accordance with some aspects of present application. As shown in FIG. 4, the NAND memory strings 308 may include a stack structure 410. The stack structure 410 includes a plurality of gate layers 411 and a plurality of insulating layers 412 stacked alternately in a sequence and memory strings 308 extending vertically through the gate layers 411 and the insulating layers 412. The gate layers 411 and the insulating layers 412 may be stacked alternately and every two adjacent gate layers 411 are isolated from each other by one insulating layer 412. The number of the memory cells included in the memory cell array 300 may be determined by the number of the pairs of gate layers 411 and insulating layers 412 in the stack structure 410.

The material of the gate layers 411 may include a conductive material. The conductive material includes, but not limited to, tungsten (W), cobalt (Co), copper (Cu), aluminum (Al), polysilicon, doped silicon, silicide or any combination thereof. In some example, each gate layer 411 includes a metal layer, for example, a tungsten layer. In some example, each gate layer 411 includes a doped polysilicon layer. Each gate layer 411 may include control gates surrounding memory cells. The gate layer 411 at the top of the stack structure 410 may extend horizontally as an upper select gate line 413, e.g., a drain selective line or a top selective line 313, wherein the upper select gate line 413, e.g., the leading-out line of the above-mentioned DSG 312, is applied with a corresponding select voltage or deselect voltage; the gate layer 411 at the bottom of the stack structure 410 may extend horizontally as a lower select gate line 414, e.g., a source selective line or a bottom selective line 315, wherein the lower select gate line 414, e.g., the leading-out line of the SSG 310 is applied with a corresponding select voltage or deselect voltage. The gate layers 411 extending horizontally between the upper select gate line and the lower select gate line may serve as word line layers 403, e.g., the above-mentioned word lines 318.

In some implementations, the stack structure 410 may be disposed on a substrate 401. The substrate 401 may include silicon (e.g., single crystal silicon), silicon germanium (SiGe), gallium arsenide (GaAs), germanium (Ge), silicon on insulator (SOI), germanium on insulator (GOI) or any other suitable material.

In some implementations, the NAND memory string 308 may include a channel structure extending through the stack structure 410 vertically. In some example, the channel structure includes a channel hole filled with (one or more) semiconductor materials (e.g., as a semiconductor channel) and (one or more) dielectric materials (e.g., as a memory film). In some example, the semiconductor channel includes silicon, for example, polysilicon. In some example, the memory film is a composite dielectric layer including a tunneling layer, a storage layer (further referred to as a “charge trapping/storage layer”) and a blocking layer. The channel structure may have a cylinder shape (e.g., a pillar shape). In accordance with some example, the semiconductor channel, the tunneling layer, the storage layer and the blocking layer are arranged radially from the center to the outer surface of the pillar in this order. The tunneling layer may include silicon oxide, silicon oxynitride or any combination thereof. The storage layer may include silicon nitride, silicon oxynitride or any combination thereof. The blocking layer may include silicon oxide, silicon oxynitride, a high-k dielectric or any combination thereof. In one example, the memory film may include a composite layer of silicon oxide/silicon oxynitride/silicon oxide (ONO).

Referring back to FIG. 1, the peripheral circuits 20 may be coupled to the memory cell array 300 through bit lines 316, world lines 318, source lines 314, SSG lines 315 and DSG lines 313. The peripheral circuits 20 may include any suitable analog, digital, and mixed-signal circuits and thus used to facilitate operations of the memory cell array 300 by applying at least one of voltage signals or current signals to and sensing at least one of voltage signals or current signals from each target memory cells 306 through bit lines 316, word lines 318, source lines 314, SSG lines 315 and DSG lines 313.

Referring back to FIG. 1, peripheral circuits 20 may include a page buffer (PB)/sense amplifier 20-04, a column decoder/bit line driver 20-06, a row decoder/word line driver 20-08, a voltage generator 20-10, a control logic unit 20-12, registers 20-14, an interface 20-16, and a data bus 20-18. It should be understood that in some examples additional circuits not shown in FIG. 1 may further be included.

Specifically, the page buffer/sense amplifier 20-04 may be configured to read and program (write) data from/to the memory cell array 300 according to control signals from the control logic unit 20-12. In one example, the page buffer/sense amplifier 20-04 may store programming data (writing data) to be programmed into the memory cells coupled to one word line in the memory cell array 300. In another example, the page buffer/sense amplifier 20-04 may perform verify operations for programming to ensure that the data have been properly programmed into the memory cells 306 coupled to the selected word lines 318. In still another example, the page buffer/sense amplifier 20-04 may further sense low power signals from the bit line 316 that represent data bits stored in the memory cells 306 and amplify the small voltage swings to recognizable logic levels in a read operation. The column decoder/bit line driver 20-06 can be configured to be controlled by the control logic unit 20-12 and select one or more NAND memory strings 308 by applying bit line voltages generated from voltage generator 20-10.

The row decoder/word line driver 20-08 can be configured to be controlled by the control logic unit 20-12 and select/deselect memory blocks 304 of the memory cell array 300 and select/deselect word lines 318 of a memory block 304. The row decoder/word line driver 20-08 can be further configured to drive word lines 318 using word line voltages generated from the voltage generator 20-10. In some example, the row decoder/word line driver 20-08 can further select/deselect and drive the SSG lines 315 and the DSG lines 313. As described below in detail, the row decoder/word line driver 20-08 is configured to perform erase operations on the memory cells 306 coupled to (one or more) selected word lines 318. The voltage generator 20-10 can be configured to be controlled by the control logic 20-12 and generate the word line voltages (e.g., a read voltage, a program voltage, a pass voltage, a local voltage, a verification voltage, etc.), bit line voltages, and source line voltages to be supplied to memory cell array 300.

Here, the control logic unit 20-12 may be coupled to each peripheral circuit described above and configured to control operations of each peripheral circuit. The registers 20-14 may be coupled to the control logic unit 20-12 and include a status register, a command register and an address register for storing status information, command operation codes (OP codes) and command addresses for controlling operations of each peripheral circuit. The interface 20-16 may be coupled to the control logic unit 20-12 and serve as a control buffer to buffer control commands received from the host (not shown) and relay them to the control logic unit 20-12, and buffer status information received from the control logic unit 20-12 and relay them to the host. The interface 20-16 may be further coupled to the column decoder/bit line driver 20-06 through the data bus 20-18 and serve as a data I/O interface and data buffer to buffer data and relay it to the memory cell array 300 or relay or buffer data from the memory cell array 300.

In implementations of the present application, the peripheral circuits 20 may further include a storage structure 20-20 that may include a static random access memory (SRAM). For this type of storage structure, the so-called “static” means that data stored in the storage structure can be retained if only power is on. The storage structure may be other type of memory and can be configured according to requirements for the memory device. In implementations of the present application, technical solutions will only be explained with an SRAM taken as an example.

It is to be noted that although FIG. 1 shows a storage structure 20-20 outside the control logic unit 20-12, the present application is not limited to this. In some other example, the storage structure 20-20 may further be included in the control logic unit 20-12.

Based on the above-mentioned memory device, due to the fabrication processes and costs, NAND flashes may contain bad memory blocks when they are completed and leave the factory and the bad memory blocks are called leave-factory bad blocks. In some implementations, the information indicating whether a memory block is a bad block (abbreviated as FBB information) is stored in a latch of a row decoder corresponding to the memory block and around the latch transistors supporting the latch (e.g., circuit structures related to reading/writing of the FBB information) for controls like set/reset/sensing are included. The above-mentioned circuit including the latch and constituted by transistors for storage of FBB information is disposed in each row decoder corresponding to a memory block.

In some other implementations, row decoders store no FBB information of memory blocks and FBB information of each memory block is stored in the storage structure 20-20 within the peripheral circuits 20. When a related operation needs to be performed on a memory block, the FBB information corresponding to the memory block can be read from the storage structure to determine whether the related operation can be performed on the memory block. Using this design, the row decoder corresponding to each memory block can have no latch for storage of FBB information and circuit structures related to reading/writing of FBB information disposed therein, simplifying the circuitry of the row decoder and saving the critical area.

The specific operations may be as follows: by the peripheral circuits 20, receiving and parsing an operation command to obtain at least one piece of address information; then the corresponding state information of the memory block to be operated is read from the storage structure according to each piece of address information. Then it is determined whether a corresponding operation is to be performed on the corresponding memory block to be operated according to the state corresponding to each memory block to be operated. Here, in response to the state information of a memory block to be operated indicates that the memory block to be operated is a bad block, generate a stop signal; the stop signal indicates to cease performing the operations the memory block to be operated (or inactivation of the memory block to be operated). Here, the so-called “activation” may be understood as “being selected”. For example, when a memory block to be operated is determined to be a bad block, it cannot be selected, e.g., cannot be operated. Here, the so-called state information is the above-described FBB information used to indicate whether a memory block is a leave-factory bad block. Here, the so-called operation is a collective name that may include at least one of the following first operation or a second operation. The so-called stop signal is further a collective name that may include at least one of a first stop signal or a second stop signal. Likewise, the following operation signal is further a collective name that has different meaning in a different instance. For example, during an operation for a single plane, the operation signal may include a first operation signal; for another example, during an operation for multiple planes, the operation signal may include a first operation signal and a second operation signal.

Here, the address information may be information used to indicate the location of a memory block in the memory cell array.

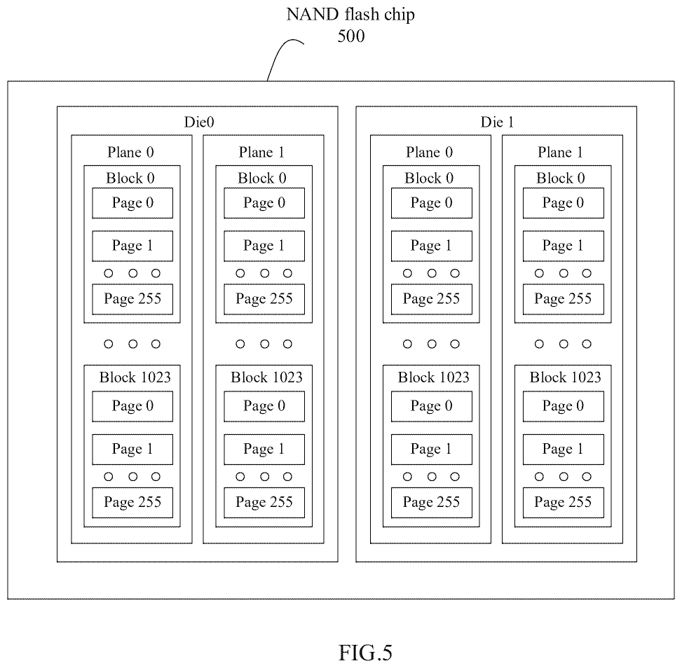

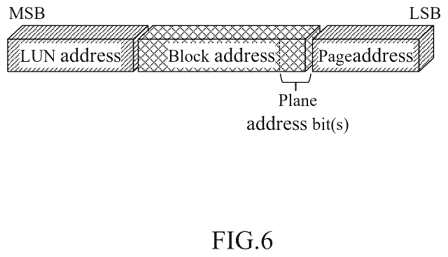

Illustratively, refer to FIG. 5, which shows an architecture diagram illustrating the inside of an NAND flash chip in accordance with an implementation of the present application. In FIG. 5, the flash chip 500 may include Die0 and Die1, wherein each of Die0 and Die1 includes two planes (Plane0 and Plane1). Each plane contains a plurality of memory blocks, for example, Block0 to Block1023. Each memory block includes a plurality of memory pages, for example, Page0 to Page255 and a page here may refer to a logic page having a capacity that may be larger than, equal to or smaller than that of the above-mentioned memory page. It is to be noted that the structure in FIG. 5 is only for illustration and during practical usage the numbers of dies, planes, blocks and pages included in a memory array may be designed according to practical conditions. During practical usage, based on the flash chip as shown in FIG. 5, in order to access those storage resources, row address and column address are used and the column address is offset address within a page. A row address may be defined as shown in FIG. 6 and may be a logical unit number (LUN) address, a block address and a page address in the order from MSB to LSB. The LUN address corresponds to access of a die described above. A block address is used to access a memory block in a die and the lowest bit thereof is a plane address. A plane address is used to access a memory plane in a memory block. A page address is used to access a memory page (e.g., page) in a block. For example, the address information may include an LUN address and a block address. It is to be noted that the first operation described above may be one of a program operation, an erase operation and a read operation. Since the program operation and the read operation are performed in the unit of a page, the address information may further include an LUN address, a block address and a page address.

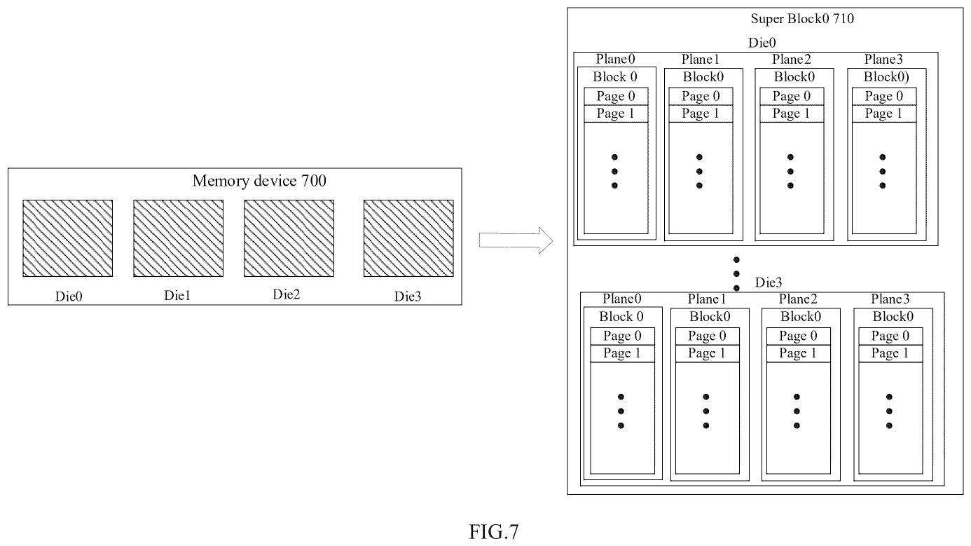

During practical applications, the data to be stored may be stored in one memory block, or may be stored in a plurality of memory blocks in some way. When the data to be stored is stored in a plurality of memory blocks, those memory blocks are referred to as super blocks (SPB). Super block are defined according to different performance of different memory devices and user demands. For example, a super memory block can be defined to be constituted by blocks of the same number taken from dies of the memory device. For example, if a memory device 700 as shown in FIG. 7 includes 4 dies (Die0, Die1, Die2 and Die3), each die include 4 memory planes (Plane0, Plane1, Plane2 and Plane3), each plane includes a plurality of memory blocks (Block0, Block1, Block2 . . . . Block n) and each block includes a plurality of pages, in this structure, a super block is constituted by blocks of the same number taken from the dies of the memory device. For example, Super Block0 710 as shown in FIG. 7 includes Block0 of each plane in each die of Die0, Die1, Die2 and Die3. Other SPBs are defined in a similar way. In this case, the memory block(s) corresponding to the at least one piece of address information may constitute a super block and the memory block corresponding to each piece of address information may be located in a different plane.

For example, the at least one piece of address information may include one or more of address information. When the at least one piece of address information includes one, the memory device is in a single-plane operation mode, e.g., a related operation (e.g., the first operation) is performed on one memory block to be operated; when the at least one piece of address information includes multiple, the memory device is in a multiple-plane operation mode, and a related operation (e.g., the first operation) is performed simultaneously on the memory blocks included in a plurality of planes.

Based on the description above, the storage structure may include an SRAM having a block state information table buffered therein. The state information of individual memory blocks included in a memory cell array is recorded in the block state information table, and each piece of state information includes a first flag or a second flag. The first flag is used to indicate a corresponding memory block is a bad block and the second flag is used to indicate a corresponding memory block is a normal block.

Illustratively, each first flag occupies one bit in the SRAM and each second flag occupies one bit in the SRAM.

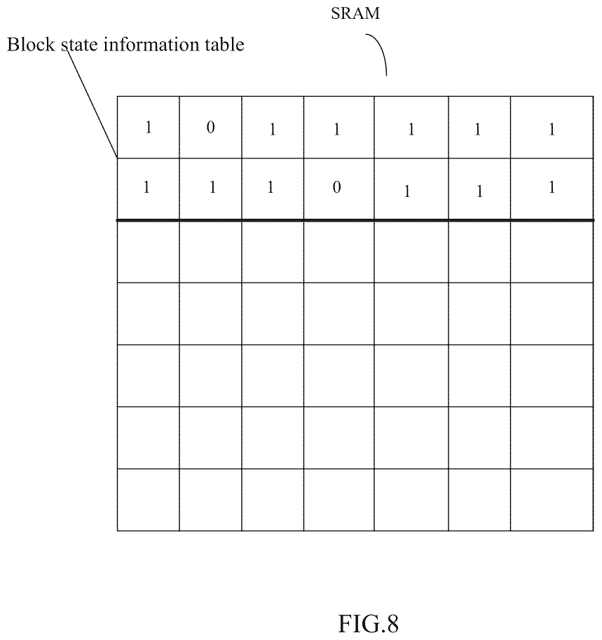

Illustratively, the first flag may be 0 or 1, and correspondingly the second flag may be 1 or 0. Specifically and illustratively, as shown in FIG. 8, a structural diagram of a block state information table stored in the SRAM is illustrated. In FIG. 8, each small box represents one bit, e.g., one flag in one piece of state information.

Here, each piece of state information indicates a leave-factory state of a corresponding memory block in the memory cell array. The leave-factory state includes a memory block is a bad block or a memory block is a normal block. For example, whether a memory block is a bad block when leaving the factory is characterized by the first flag and the second flag. Illustratively, a first flag being included in the state information corresponding to a memory block indicates that the memory block is a bad block when leaving the factory; a second flag being included in the state information corresponding to a memory block indicates that the memory block is a normal block.

In some examples, the block state information table is stored at a dedicated location in the memory cell array; the peripheral circuits are further configured to: when the memory device is powered on, perform a loading operation to buffer the block state information table into the SRAM.

It is to be noted that an SRAM is a volatile memory and will lost the data stored therein when the memory device loses power or has not yet been powered on. When the memory device is powered on or restores power, a loading operation is needed to buffer the block state information table into the SRAM for later use.

During practical applications, the state information of the corresponding memory block to be operated is read from the storage structure according to each piece of address information, e.g., the SRAM is accessed. One achievable example process may include: storing the mapping relationship between address information of memory blocks and storage addresses of state information in the control logic unit; obtaining address information corresponding to a memory block through parsing by the control logic unit included in the peripheral circuits; determining the storage address of the corresponding state information in the SRAM according to the mapping relationship and the address information obtained by the parsing, the storage address including a row address and a column address; and reading the state information of the memory block based on the row address and the column address. Alternatively, another achievable example process may include: modifying the transport protocol between the memory controller and the memory device, and incorporating address information of memory blocks and storage addresses of state information in an operation command. Then, during use, the control logic unit included in the peripheral circuits receives and parses the operation command to obtain the above-mentioned address information and the storage address of the state information of the memory block corresponding to the address information, and reads the state information of the memory block based on the row address and column address contained in the storage address.

Based on the description above, when the at least one piece of address information includes one, the memory device is in the single-plane operating mode. When the at least one piece of address information includes multiple, the memory device is in the multiple-plane operation mode.

Some operations of the memory device in an implementation of the present application in the single-plane operating mode and the multiple-plane operation mode will be described in detail.

In some implementations, the peripheral circuits may be further configured to: in response to the at least one piece of address information including a first piece of address information, read, from the storage structure, the state information of a first memory block to be operated included in a first memory plane according to the first piece of address information; and in response to the state information of the first memory block to be operated indicating that the first memory block to be operated is a bad block, generate a first stop signal that indicates to cease performing a first operation on the first memory block to be operated.

For example, in the single-plane operation mode, when the at least one piece of address information includes the first piece of address information, the peripheral circuits read, from the storage structure, the state information of the corresponding first memory block to be operated according to the first piece of address information and cease performing first operation on the first memory block to be operated when the read state information indicates the first memory block to be operated is a bad block.

In some implementations, an example process of ceasing performing the first operation on the first memory block to be operated may be as follows. When the control logic unit included in the peripheral circuits determines the first memory block to be operated is a bad block, generate the first stop signal used to indicate the row decoder not to charge the word lines and bit lines included in the first memory block to be operated. Illustratively, the specific operation may be as follows. When the control logic unit included in the peripheral circuits determines the first memory block to be operated is a bad block, generate the first stop signal. The stop signal is sent to the row decoder, so that the row decoder do not charge the word lines and bit lines of the first memory block to be operated and therefore the first operation is ceased on the first memory block to be operated. For example, when the first memory block to be operated is determined to be a bad block, the row decoder, in response to the first stop signal, will not turn on the switch for charging the related word lines and bit lines included in the first memory block to be operated, for example, the MOS transistor will not be turned on, e.g., the related word lines and bit lines included in the first memory block to be operated will not be charged.

In some implementations, when the first operation is prohibited from being performed on the first memory block to be operated, the peripheral circuits may further feed a signal indicating operation failure to the memory controller or the host. It should be noted that the operation failure may refer to the situation, in which the first operation is prohibited from being performed on the first memory block to be operated.

In some implementations, the peripheral circuits may be further configured to: in response to the state information of the first memory block to be operated indicating that the first memory block to be operated is not a bad block, generate a first operation signal that indicates to perform the first operation on the first memory block to be operated, wherein the first operation may include one of an erase operation, a program operation, or a read operation.

For example, in the single-plane operation mode, when the peripheral circuits determine that the first memory block to be operated is not a bad block according to the read state information corresponding to the first memory block to be operated, generate the first operation signal that is used to indicate to perform the first operation on the first memory block to be operated. Here, the first operation may be an erase operation, or a program operation or a read operation. It is to be noted that when the first memory block to be operated is not a bad block, it may be an unused new memory block, and since data has not yet been stored in the new memory block, the first operation may be an erase operation or a program operation; or the first memory block to be operated may be a used memory block, e.g., has some data stored therein, and then the first operation may be an erase operation, or a program operation or a read operation.

In some implementations, an example process of enabling the first operation on the first memory block to be operated may be as follows. When the control logic unit included in the peripheral circuits determine that the first memory block to be operated is not a bad block, generate a first operation signal which is sent to the corresponding row decoder. In response to the first operation signal, the row decoder turns on the switch for charging the word lines and bit lines included in the first memory block to be operated to charge the word lines and bit lines included in the first memory block to be operated and thereby perform the first operation on the first memory block to be operated.

In some implementations, the peripheral circuits may be further configured to: in response to success of execution of the first operation, output a first indication signal that indicates the success of execution of the first operation.

Here, success of execution of the first operation may mean that a correct result is obtained after execution of the first operation by the memory device. For example, when the first operation is an erase operation, success of execution of the first operation may mean that erasing of data in the selected memory block is completed. For another example, when the first operation is a program operation, success of execution of the first operation may mean that a memory page in the selected memory block is programmed and passes verification. For yet another example, when the first operation is a read operation, success of execution of the first operation may mean that the data to be read is read from the selected memory block.

In practical applications, after execution of the first operation, the memory device, through an I/F interface 20-16 included in the peripheral circuits, outputs a state bit to the memory controller coupled to the memory device as described subsequently, so that the host may identify the operation condition of the first operation on the memory device. The state bit is used to reflect the execution result of the first operation. Here, the first indication signal may be a signal (or a flag) contained in the state bit reflecting success of execution of the first operation. The state bit may further contain another signal used to represent the result of operation failure of the first operation. It is to be noted that the operation failure here may mean that the first operation is performed, but no correct result is obtained. For example, when the first operation is an erase operation, the data stored in the first memory block to be operated is not erased; for another example, when the first operation is a program operation, a memory page included in the first memory block to be operated fails to pass verification after the program operation; for yet another example, when the first operation is a read operation, erroneous data or no data is read from the first memory block to be operated.

For example, the signal output by the memory device to indicate operation failure may include the above-described two instances. In one of them, the memory block to be operated is a leave-factory bad block and in the other one, the first operation is not performed successfully. The memory device can define different flags for two instances to distinguish them.

In some implementations, the peripheral circuits may be further configured to: in response to the at least one piece of address information further including a second piece of address information, read, from the storage structure, the state information of a second memory block to be operated included in a second memory plane according to the second piece of address information, wherein the number of the second piece of address information is one or two; and in response to the state information of the second memory block to be operated indicating that the second memory block to be operated is a bad block, generate a second stop signal that indicates to cease performing a second operation on the second memory block to be operated.

It is to be noted that the second operation here may be the same operation as the above-mentioned first operation. For example, the first memory block to be operated and the second memory block to be operated may be one of the super memory blocks described above and located in different planes, e.g., in a first memory plane and a second memory plane respectively. In this case, the memory device performs a multiple-plane operation. That is, in the multiple-plane operational mode, the peripheral circuits may read, from the storage structure, the state information corresponding to the first memory block to be operated according to the first piece of address information and the state information corresponding to the second memory block to be operated according to the second piece of address information, determine whether the first memory block to be operated is a bad block according to the state information corresponding to the first memory block to be operated and whether the second memory block to be operated is a bad block according to the state information corresponding to the second memory block to be operated, and in turn determine whether the first operation is to be performed on the first memory block to be operated and whether the second operation is to be performed on the second memory block to be operated, the second operation being the same operation as the first operation.

Specifically, in some implementations, when the state information corresponding to the first memory block to be operated indicates that the first memory block to be operated is a bad block and the state information corresponding to the second memory block to be operated indicates that the second memory block to be operated is a bad block, the first operation needs not to be performed on both the first memory block to be operated and the second memory block to be operated.

In some implementations, when the state information corresponding to the first memory block to be operated indicates that the first memory block to be operated is a bad block and the state information corresponding to the second memory block to be operated indicates that the second memory block to be operated is not a bad block, a second stop signal is generated for the first memory block to be operated and the first operation will not be performed on the first memory block to be operated, while a second operation signal is generated for the second memory block to be operated and the first operation is performed on the second memory block to be operated.

In some implementations, when the state information corresponding to the first memory block to be operated indicates that the first memory block to be operated is not a bad block and the state information corresponding to the second memory block to be operated indicates that the second memory block to be operated is a bad block, the second operation signal is generated for the first memory block to be operated and the first operation is performed on the first memory block to be operated, while the second stop signal is generated for the second memory block to be operated and the first operation will not be performed on the second memory block to be operated.

In some implementations, when the state information corresponding to the first memory block to be operated indicates that the first memory block to be operated is not a bad block and the state information corresponding to the second memory block to be operated indicates that the second memory block to be operated is not a bad block, the second operation signal is generated for both the first memory block to be operated and the second memory block to be operated, and the first operation is performed on both the first memory block to be operated and the second memory block to be operated.

For example, during a multiple-plane operation, the first operation is performed on the memory block to be operated that is not a bad block and will not be performed on other remain memory block to be operated that is a bad block.

In some implementations, the peripheral circuits may be further configured to: in response to the state information of the second memory block to be operated indicating that the second memory block to be operated is not a bad block, generate the second operation signal that indicates to perform the second operation on the second memory block to be operated, and in response to success of execution of both the first operation and the second operation, generate a second indication signal that indicates the success of execution of both the first operation and the second operation.

it is to be noted that during a multiple-plane operation, only when the first operation is successfully performed on both the first memory block to be operated and the second memory block to be operated, the second indication signal is output to inform the memory controller or the host the result of the first operation performed by the memory device. It should be understood that in other circumstances, for example, when the first operation is not successfully performed on at least one of the first memory block to be operated or the second memory block to be operated, or the first operation is not performed on the first memory block to be operated and the second memory block to be operated at all, an indication signal representing operation failure is output. In practical example, the indication signal may be designed to distinguish the two instances of operation failure.

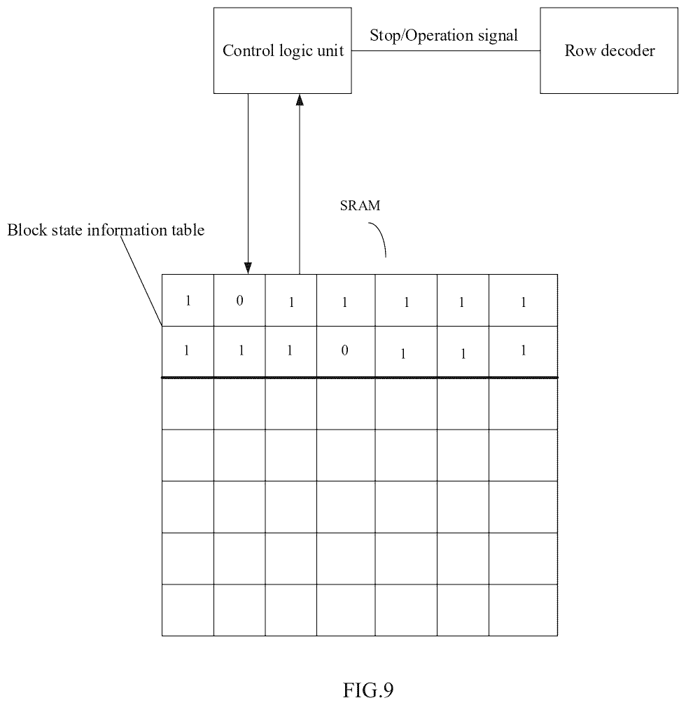

In order for the present application to be understood, as shown in FIG. 9, a flow chart of identifying whether a memory block to be operated is a bad block and whether a related operation is to be performed is provided in an implementation of the present application. As shown in FIG. 9, the flow may include: by the control logic unit of the peripheral circuits, receiving an operation command, identifying at least one piece of address information, and reading the corresponding state information from the SRAM according to each piece of address information. When a piece of state information indicates that the corresponding memory block to be operated is a bad block, generate a stop signal which indicates to cease charging on the word lines and bit lines included in the corresponding memory block to be operated, the stop signal and the corresponding address information are sent to a row decoder, and the row decoder do not perform first operation on the memory block to be operated according to the stop signal and the corresponding address information. When a piece of state information indicates that the corresponding memory block to be operated is not a bad block, generate an operation signal which is used to indicate execution of charging on the word lines and bit lines included in the corresponding memory block to be operated, the operation signal and the corresponding address information are sent to a row decoder, and the row decoder performs charging and in turn the first operation on the memory block to be operated according to the stop signal and the corresponding address information.

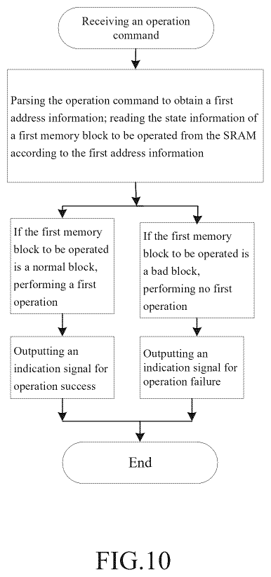

For the single-plane operation as shown in FIG. 10, the main flow may include: by the peripheral circuits, receiving and parsing an operation command to obtain a piece of address information; reading the state information of the corresponding memory block to be operated from the SRAM according to the address information; determining whether the memory block to be operated is a bad block according to the state information; if it is a bad block, no first operation is performed, and an indication signal for operation failure is output to indicate the no-operation failure; or if it is a normal block, a first operation is performed, for success of the operation, an indication signal for operation success is output and for failure of the operation, an indication signal for operation failure is output to indicate operation failure.

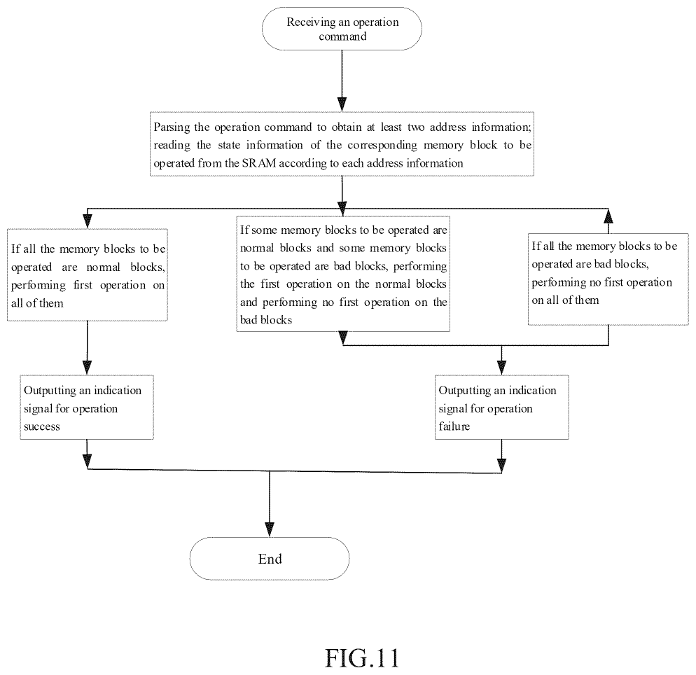

For the multiple-plane operation as shown in FIG. 11, the main flow may include: by the peripheral circuits, receiving and parsing an operation command to obtain at least two pieces of address information; reading the state information of the corresponding memory block to be operated from the SRAM according to each piece of address information; determining whether the corresponding memory block to be operated is a bad block according to each piece of state information; if all the memory blocks to be operated are normal blocks (e.g., not bad blocks), performing first operation on all the memory blocks to be operated and when the first operation is successfully performed, outputting an indication signal for operation success; if some memory blocks to be operated are normal blocks and some memory blocks to be operated are bad blocks, the first operation is performed on the memory blocks to be operated that are normal blocks and no first operation is performed on the memory blocks to be operated that are bad blocks, and at this point no matter what execution result of first operation, the indication signal for operation failure will be output; and if all the memory blocks to be operated are bad blocks, no first operation is performed and the indication signal for operation failure is further output.

In implementations of the present application, a storage structure (e.g., an SRAM) is disposed in the peripheral circuits is used to store the information indicating the leave-factory state (e.g., the above-mentioned state information) of the individual memory blocks in a memory cell array. During subsequent use, whether a memory block to be operated is a bad block can be determined only by reading the related state information from a storage structure. Using this design, one or more SRAMs can be disposed at only one location, so that complexity of the circuits within a row decoder can be reduced, the area occupied by a row decoder can be decreased to distribute more area to critical devices (e.g., a word line driver requiring a relatively high program voltage) of a memory device to increase their sizes properly, and in turn better read/write performance of the memory device can be achieved.

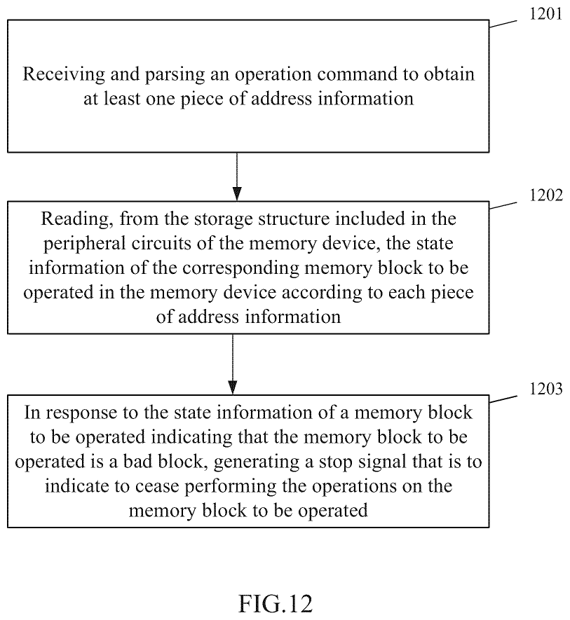

Based on the same inventive concept, as shown in FIG. 12, implementations of the present application further provide a method of operating a memory device. The operating method may include:
in operation 1201, receiving and parsing an operation command to obtain at least one piece of address information;
in operation 1202, reading, from the storage structure included in the peripheral circuits of the memory device, the state information of the corresponding memory block to be operated in the memory device according to each piece of address information;
in operation 1203, in response to the state information of a memory block to be operated indicating that the memory block to be operated is a bad block, generating a stop signal that indicates to cease performing the operations on the memory block to be operated.

In some implementations, the method further includes: in response to the at least one piece of address information including a first piece of address information, reading, from the storage structure, the state information of a first memory block to be operated included in a first memory plane according to the first piece of address information; and in response to the state information of the first memory block to be operated indicating that the first memory block to be operated is a bad block, generating a first stop signal that indicates to cease performing a first operation on the first memory block to be operated.

In some implementations, the method further includes: in response to the state information of the first memory block to be operated indicating that the first memory block to be operated is not a bad block, generating a first operation signal that indicates to perform the first operation on the first memory block to be operated, wherein the first operation may include one of an erase operation, a program operation, or a read operation.

In some implementations, the method further includes: in response to success of execution of the first operation, outputting a first indication signal that indicates the success of execution of the first operation.

In some implementations, the method further includes: in response to the at least one piece of address information further including a second address information, reading, from the storage structure, the state information of a second memory block to be operated included in a second memory plane of the memory device according to the second piece of address information, wherein the number of the second piece of address information is one or two; and in response to the state information of the second memory block to be operated indicating that the second memory block to be operated is a bad block, generating a second stop signal that indicates to cease performing a second operation on the second memory block to be operated.

In some implementations, the method further includes: in response to the state information of the second memory block to be operated indicating that the second memory block to be operated is not a bad block, generating the second operation signal that indicates to perform the second operation on the second memory block to be operated, and in response to success of execution of both the first operation and the second operation, outputting a second indication signal that indicates the success of execution of both the first operation and the second operation.

In some implementations, the storage structure includes an SRAM having a block state information table buffered therein. The state information of individual memory blocks included in a memory cell array is recorded in the block state information table, and each piece of state information includes a first flag or a second flag. The first flag is used to indicate a corresponding memory block is a bad block and the second flag is used to indicate a corresponding memory block is a normal block.

In some implementations, the state information indicates a leave-factory state of a corresponding memory block in the memory cell array. The leave-factory state includes whether a memory block is a bad block or a normal block.

In some implementations, the block state information table is stored at a dedicated location in the memory cell array of the memory device; the method further includes: when the memory device is powered on, performing a loading operation to buffer the block state information table into the SRAM.

It is to be noted that the method of operating a memory device in the implementation of the present application is substantially based on the same inventive concept as some operations in the peripheral circuits of the memory device as described above, and the terms here has been explained above in detail and will not be repeated for brevity.

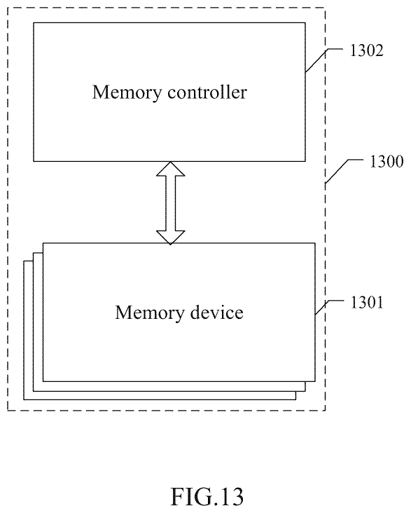

As shown in FIG. 13, implementations of the present application further provide a memory system 1300, which includes one or more memory devices 1301 according to any implementation above and a memory controller 1302 coupled to and is configured to control the memory device(s).

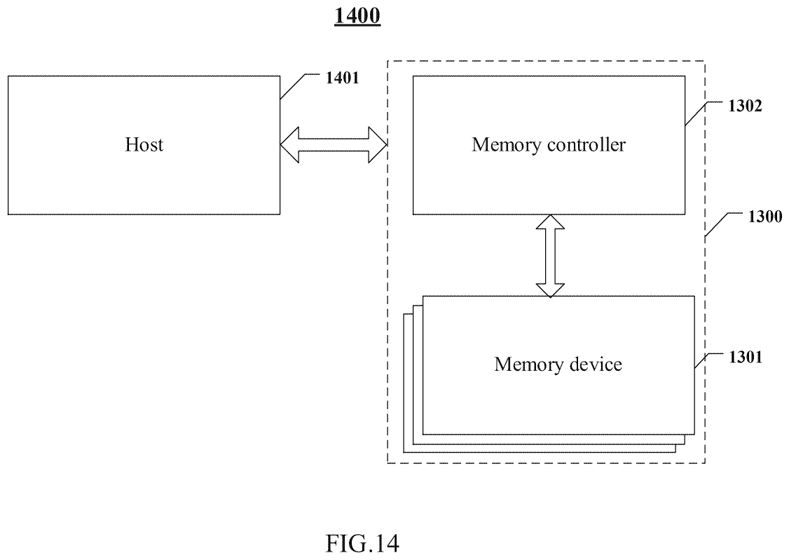

It is to be noted that the memory system may communicate with a host. Here, at least one of the host or the memory system 1300 may be included in various products such as Internet of Things (IOT) devices such as refrigerators or other devices, sensors, motors, mobile communication devices, automobiles, unmanned cars for supporting processing, communication or control of products. In some implementations, as shown in FIG. 14, a schematic diagram of an example system having a memory system in accordance with an implementation of the present application is illustrated. In FIG. 14, the system 1400 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic apparatus having memories therein. As shown in FIG. 14, the system 1400 may include a host 1401 and a memory system 1300, wherein the memory system 1300 has one or more memory devices 1301 and a memory controller 1302, the host 1401 may be a processor of the electronic apparatus such as a central processing unit (CPU) or a system-on-chip (SoC), in which the SoC may be for example an application processor (AP). The host 1401 may be configured to send data to or receive data from each memory device 1301. Specifically, each memory device 1301 may be any of the memories disclosed in the present application. For example, it can be a phase change random access memory (PCRAM), a three dimensional NAND flash or the like.

According to some example, the memory controller 1302 is coupled to each memory device 1301 and the host 1401. The memory controller 1302 is further be configured to control each memory device 1301. The memory controller 1302 can manage the data stored in each memory device 1301 and communicate with the host 1401. In some implementations, the memory controller 1302 is designed for operating in a low duty-cycle environment such as secure digital (SD) cards, compact Flash (CF) cards, universal serial bus (USB) Flash drives, or other media for use in electronic apparatuses of low duty-cycle environments such as personal computers, digital cameras, mobile phones, etc. In some implementations, the memory controller 1302 is designed to operate in high duty cycle environments such as solid state drives (SSDs) or embedded multimedia cards (cMMCs), wherein SSDs or eMMCs are used as e.g., data storage and enterprise memory arrays of the mobile devices of high duty cycle environments such as smart phones, tablet computers and laptop computers. The memory controller 1302 can be configured to control operations of the memory device 1301, such as read, erase, and program operations. The memory controller 1302 can further be configured to manage various functions with respect to the data stored or to be stored in each memory device 1301, including but not limited to bad-block management, garbage collection, logical-to-physical address conversion and wear leveling. In some example, the memory controller 1302 is further configured to process error correction codes (ECCs) with respect to the data read from or written to each memory device 1301. Any other suitable functions may be performed by the memory controller 1302 as well, for example, formatting each memory device 1301. The memory controller 1302 can communicate with an external device (e.g., the host 1401) according to a particular communication protocol. For example, the memory controller 1302 may communicate with the external device through at least one of various interface protocols, such as a USB protocol, an MMC protocol, a peripheral component interconnection (PCI) protocol, a PCI-express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

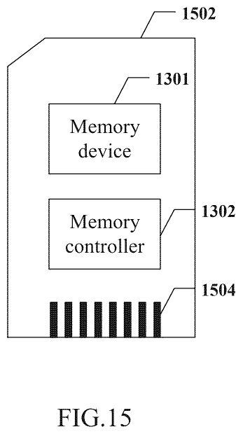

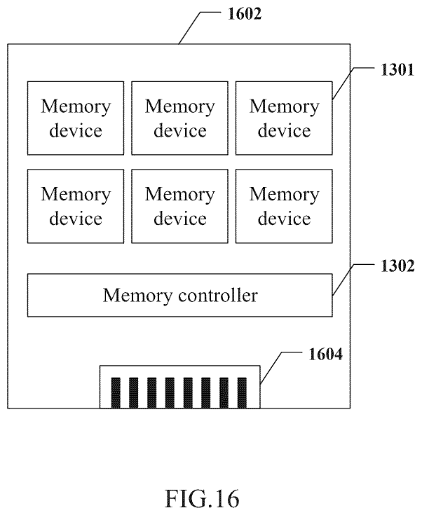

In some implementations, the memory controller 1302 and one or more memory devices 1301 can be integrated into various types of storage apparatuses, for example, be included in the same package, such as a universal Flash storage (UFS) package or an eMMC package. For example, the memory system 1300 can be implemented and packaged into different types of electronic end products. In one example as shown in FIG. 15, the memory controller 1302 and a single memory device 1301 can be integrated into a memory card 1502. The memory card may include a PC card (PCMCIA, Personal Computer Memory Card International Association), a CF card, a smart media (SM) card, a memory stick, a multimedia card (MMC, RS-MMC, MMCmicro), an SD card (SD, miniSD, microSD, SDHC), a UFS etc. The memory card may further include a memory card connector 1504 coupling the memory card to the host (e.g., the host 1401 in FIG. 14). In another example as shown in FIG. 16, the memory controller 1302 and multiple memory devices 1301 can be integrated into a solid state drive (SSD) 1602. The SSD may further include an SSD connector 1604 coupling the SSD to the host (e.g., the host 1401 in FIG. 14). In some example, at least one of the memory capacity or operating speed of an SSD are greater than at least one of the memory capacity or operating speed of a memory card. Furthermore, the memory controller 1302 can be further configured to control erase, read and write operations of the memory devices 1301.

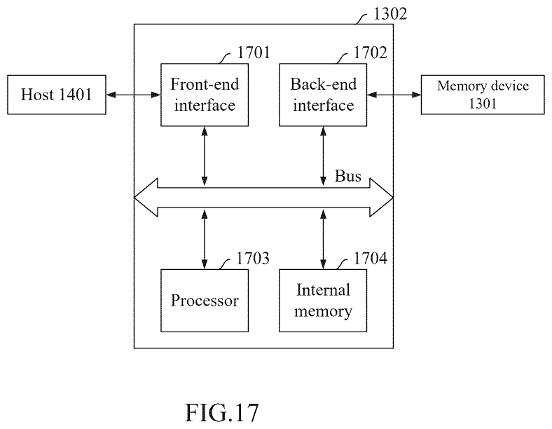

See FIG. 17, which illustrates an example structural diagram of a memory controller provided in an implementation of the present application. As shown in FIG. 17, the memory controller may include: a front-end interface 1701, a back-end interface 1702, a processor 1703 and an internal memory 1704, wherein the above-mentioned components 1701, 1702, 1703 and 1704 in the memory controller 1302 may share signals transferred inside the memory controller 1302 through an internal bus. In some implementations, the front-end interface 1701 may connect the host with the memory system 1300 interface in response to the protocol of the host coupled to the memory system 1300 and the front-end interface 1701 may exchange transfer commands and data operations between the host and the memory system 1300. The front-end interface 1701 may process commands and data sent by the host and may include at least one of: a universal serial bus (USB), a multimedia card (MMC), a peripheral component interconnect express (PCI-e or PCIe) interface, a small computer system interface (SCSI), a serial SCSI (SAS), a serial advanced technology attachment (SATA) interface, a parallel advanced technology attachment (PATA) interface, a small computer system interface (SCSI), an enhanced small disk interface (ESDI) and an electronic integrated driver (IDE). In some implementations, the front-end interface 1701 is component, through which the memory system 1300 exchanges data with the host, and can be implemented through firmware referred to as a host interface layer (HIL).

The back-end interface 1702 may be an interface for transmission of commands and data between memory controller 1302 and the coupled memory device, enabling the memory controller 1302 to control the coupled memory device in response to a request transferred from the host. The back-end interface 1702 may generate control signals for control of the coupled memory device. In some implementations, if the coupled memory device is an NAND flash memory, the back-end interface 1702 may write data into or read data from the coupled memory device under the control by the processor 1703. The back-end interface 1702 may process commands and data between the memory controller 1302 and the coupled memory device, for example, operations of the NAND flash interface, in particular operations between the memory controller 1302 and the coupled memory device. In accordance with an implementation, the back-end interface 1702 may be implemented as a component for data exchange with the coupled memory device by firmware referred to as a flash interface layer (FIL).

The processor 1703 may be implemented as a microprocessor or a central processing unit (CPU). The memory system 1300 may include one or more processors 1703. The processor(s) 1703 may control all the operations of the memory system 1300. For example rather than limitation, the processor 1703 may control program or read operations of the coupled memory device in response to a write request or a read request from the host. In accordance with an implementation, the processor 1703 may control all the operations of the memory system 1300 by using or executing firmware. In the present application, the firmware may be referred to as a flash translation layer (FTL). FTL can function as an interface between the host and the coupled memory device. The host can transmit requests related to write and read operations to the coupled memory device through the FTL. For example, when an operation requested by the host is performed on the coupled memory device, the memory controller 1302 uses the processor 1703. The processor 1703 coupled to the coupled memory device may process indications and commands related to the command from the host. The memory controller 1302 may perform foreground operations such as command operations corresponding to the commands input from the host, for example, program operations corresponding to a write command, read operations corresponding to a read command, erase/discard operations related to an erase/discard command and parameter setting operations corresponding to a parameter setting command or a characteristic setting command having a setting command.

For another example, the memory controller 1302 may perform background operations on the coupled memory device through the processor 1703. For example rather than limitation, the background operations include a garbage collection (GC) operation, a wear leveling (WL) operation and a bad block management operation for checking and searching bad blocks. The garbage collection operation may include an operation for copying and processing the data stored in a memory block to another memory block in the memory device. The wear leveling operation may include an operation for exchanging and processing the stored data between memory blocks of the memory device. The bad block management operation may include checking and processing bad blocks in memory block of the coupled memory device.

The internal memory 1704 may be a working memory of the memory controller 1302 configured to store data for driving the memory controller 1302. Specifically, when the memory controller 1302 controls the memory device in response to a request from the host, the internal memory 1704 may store firmware driven by the processor 1703 and the data required for driving firmware (e.g., metadata). The internal memory 1704 may further be a buffer memory of the memory controller 1302 configured to temporarily store the data to be written that is transferred to the coupled memory device from the host and the read data transmitted from the coupled memory device to the host. The internal memory 1704 may include a program memory, a data memory, a write buffer/cache, a read buffer/cache, a data buffer/cache and a mapping buffer/cache used to store the date to be written and the read data. The internal memory 1704 may be implemented using a volatile memory. The internal memory 1704 may be implemented using an SRAM, a DRAM or both.

Although FIG. 17 shows an internal memory 1704 included in the memory controller 1302, the present application is not limited to this. In an implementation, the internal memory 1704 may be included outside the memory controller 1302, and the memory controller 1302 may input and output data to the internal memory 1704 through a separate memory interface (not shown). In some implementations, the host may dedicate a portion of the capacity of the internal memory to an SSD, and the memory controller of the SSD invokes a portion of the capacity of internal memory in the host as its own internal memory through the front-end interface, e.g., using the host memory buffer (HBM) technology. For the memory device 1301, e.g., the memory device as shown in FIGS. 2 to 5, no repetition will be made here. It is to be noted that some operations of the memory device have been discussed above in detail and the contents here can be understood with reference to the foregoing description, so that no repetition will be made here.

It is to be noted that the memory system includes the above-mentioned memory device and thus both of them have the same technical features. Terms that appear in the memory system have been explained in detail in the above-mentioned memory device and apply equally herein, so that no repetition will be made here.

Only relatively preferable implementations are described above and they are not used to limit the scope claimed by the present application.

What is claimed is:

1. A memory device, comprising:
a memory cell array comprising at least one memory block; and
a peripheral circuit coupled to the memory block and comprising a storage structure, wherein the peripheral circuit is configured to:
receive and parse an operation command to obtain at least one piece of address information;
read, from the storage structure, state information of a corresponding memory block to be operated according to each piece of address information, wherein the state information indicates whether the memory block is a bad block; and
generate a stop signal in response to state information of a memory block to be operated indicating that the memory block to be operated is a bad block, wherein the stop signal indicates to cease performing operations on the memory block to be operated.

2. The memory device of claim 1, wherein the peripheral circuit is further configured to:
in response to the at least one piece of address information comprising a first piece of address information, read, from the storage structure, state information of a first memory block to be operated included in a first memory plane according to the first piece of address information; and
in response to the state information of the first memory block to be operated indicating that the first memory block to be operated is a bad block, generate a first stop signal that indicates to cease performing a first operation on the first memory block to be operated.

3. The memory device of claim 2, wherein the peripheral circuit is further configured to:
in response to the state information of the first memory block to be operated indicating that the first memory block to be operated is not a bad block, generate a first operation signal that indicates to perform the first operation on the first memory block to be operated, wherein the first operation comprises one of an erase operation, a program operation, or a read operation.

4. The memory device of claim 3, wherein the peripheral circuit is further configured to:
in response to success of execution of the first operation, output a first indication signal that indicates the success of execution of the first operation.

5. The memory device of claim 3, wherein the peripheral circuit is further configured to:
in response to the at least one piece of address information further comprising a second piece of address information, read, from the storage structure, state information of a second memory block to be operated included in a second memory plane according to the second piece of address information, wherein a number of the second piece of address information is one or more; and
in response to the state information of the second memory block to be operated indicating that the second memory block to be operated is a bad block, generate a second stop signal that indicates to cease performing a second operation on the second memory block to be operated.

6. The memory device of claim 5, wherein the peripheral circuit is further configured to:
in response to the state information of the second memory block to be operated indicating that the second memory block to be operated is not a bad block, generate a second operation signal that indicates to perform the second operation on the second memory block to be operated; and
in response to success of execution of both the first operation and the second operation, output a second indication signal that indicates the success of execution of both the first operation and the second operation.

7. The memory device of claim 1, wherein the storage structure comprises a static random access memory (SRAM) having a block state information table buffered therein, state information of individual memory blocks included in the memory cell array is recorded in the block state information table, and each piece of state information comprises a first flag and a second flag, wherein the first flag indicates that a corresponding memory block is a bad block, and the second flag indicates that a corresponding memory block is a normal block.

8. The memory device of claim 7, wherein each piece of state information indicates a leave-factory state of a corresponding memory block in the memory cell array, wherein the leave-factory state comprises: a memory block is a bad block or a memory block is a normal block.

9. The memory device of claim 8, wherein the block state information table is stored at a dedicated location in the memory cell array, and
the peripheral circuit is further configured to:
when the memory device is powered on, perform a loading operation to buffer the block state information table into the SRAM.

10. The memory device of claim 7, wherein:
each first flag occupies one bit in the SRAM; and
each second flag occupies one bit in the SRAM.

11. An operating method of a memory device, comprising:
receiving and parsing an operation command to obtain at least one piece of address information;
reading, from a storage structure included in a peripheral circuit of the memory device, state information of a corresponding memory block to be operated in the memory device according to each piece of address information; and
generating a stop signal in response to state information of a memory block to be operated indicating that the memory block to be operated is a bad block, wherein the stop signal indicates to cease performing operations on the memory block to be operated.

12. The operating method of claim 11, further comprising:
in response to the at least one piece of address information comprising a first piece of address information, reading, from the storage structure, state information of a first memory block to be operated included in a first memory plane according to the first piece of address information; and
in response to the state information of the first memory block to be operated indicating that the first memory block to be operated is a bad block, generating a first stop signal that indicates to cease performing a first operation on the first memory block to be operated.

13. The operating method of claim 12, further comprising:
in response to the state information of the first memory block to be operated indicating that the first memory block to be operated is not a bad block, generating a first operation signal that indicates to perform the first operation on the first memory block to be operated, wherein the first operation comprises one of an erase operation, a program operation, or a read operation.

14. The operating method of claim 13, further comprising:
in response to success of execution of the first operation, outputting a first indication signal that indicates the success of execution of the first operation.

15. The operating method of claim 13, further comprising:
in response to the at least one piece of address information further comprising a second piece of address information, reading, from the storage structure, state information of a second memory block to be operated included in a second memory plane of the memory device according to the second piece of address information, wherein a number of the second piece of address information is one or more; and
in response to the state information of the second memory block to be operated indicating that the second memory block to be operated is a bad block, generating a second stop signal that indicates to cease performing a second operation on the second memory block to be operated.

16. The operating method of claim 15, further comprising:
in response to the state information of the second memory block to be operated indicating that the second memory block to be operated is not a bad block, generating a second operation signal that indicates to perform the second operation on the second memory block to be operated; and
in response to success of execution of both the first operation and the second operation, outputting a second indication signal that indicates the success of execution of both the first operation and the second operation.

17. The operating method of claim 11, wherein
the storage structure comprises a static random access memory (SRAM) having a block state information table buffered therein, state information of individual memory blocks included in the memory device is recorded in the block state information table, and each piece of state information comprises a first flag and a second flag, wherein the first flag indicates that a corresponding memory block is a bad block, and the second flag indicates that a corresponding memory block is a normal block.

18. The operating method of claim 17, wherein
the piece of state information indicates a leave-factory state of a corresponding memory block in the memory device, wherein the leave-factory state comprises: a memory block is a bad block or a memory block is a normal block.

19. The operating method of claim 18, wherein
the block state information table is stored at a dedicated location in the memory device of the memory device, and
the operating method further comprises:
when the memory device is powered on, performing a loading operation to buffer the block state information table into the SRAM.

20. A memory system, comprising:
one or more memory devices, wherein each of the one or more memory devices comprises:
a memory cell array comprising at least one memory block; and
a peripheral circuit coupled to the memory block and comprising a storage structure, wherein the peripheral circuit is configured to:
receive and parse an operation command to obtain at least one address information;
read, from the storage structure, state information of a corresponding memory block to be operated according to each address information, wherein the state information indicates whether the memory block is a bad block; and
generate a stop signal in response to state information of a memory block to be operated indicating that the memory block to be operated is a bad block, wherein the stop signal indicates to cease performing operations on the memory block to be operated; and
a memory controller that is coupled to the memory devices and configured to control the memory devices.
